(19) United States
(12) Patent Application Publication
(10) Pub. No.: US 2026/0136484 A1
(43) Pub. Date: May 14, 2026

(54) PORTABLE POWER SUPPLY

(71) Applicant: MILWAUKEE ELECTRIC TOOL CORPORATION, Brookfield, WI (US)

(72) Inventors: Peter W. Roser, Germantown, WI (US); Eliott G. Rand, Menomonee Falls, WI (US); Kyle R. Becker, Brookfield, WI (US)

(21) Appl. No.: 19/385,464

(22) Filed: Nov. 11, 2025

Related U.S. Application Data
(60) Provisional application No. 63/719,787, filed on Nov. 13, 2024.

(51) Int. Cl. H05K 5/02

(52) U.S. Cl. CPC H05K 5/023; H05K 5/0221; H05K 5/0247

(57) ABSTRACT

A portable power supply includes a housing with a power source and at least one outlet, a frame surrounding the housing, and a handle coupled to the frame. The handle has a grip, an actuator, and a tube slidable relative to the frame, with an elongated rigid member disposed in the tube. The rigid member moves along the tube upon actuation of the actuator. A lock assembly, including a lock housing, a wedge member, and a pin member, is coupled to the end of the rigid member. The lock assembly is configured to secure the portable power supply in a desired position, providing a convenient and portable source of power.

### RELATED APPLICATIONS

This application claims the benefit of U.S. Provisional Patent Application No. 63/719,787, filed Nov. 13, 2024, the entire content of which is hereby incorporated by reference.

### FIELD

The present disclosure relates to a portable power supply.

### BACKGROUND

Portable power supplies provide electricity on, for instance, a jobsite for various power tools.

### SUMMARY

The present disclosure provides, in one aspect, a portable power supply including a housing, a power source at least partially disposed in the housing and configured to supply power to at least one outlet disposed on the housing, a frame surrounding the housing, and a handle coupled to the frame. The handle includes a grip, an actuator disposed on the grip and configured for displacement upon actuation of the actuator, and a tube slidable relative to the frame and coupled to the grip at one end. The handle includes an elongated rigid member disposed in the tube. The elongated rigid member is configured to move along the tube upon actuation of the actuator. The handle includes a lock assembly having a lock housing, a wedge member, and a pin member. The wedge and pin member are received in the lock housing. The wedge member is coupled to an end of the elongated rigid member.

The present disclosure provides, in another aspect, a portable power supply including a housing including an outlet, a foot, an upper surface at least partially defining a plane the upper surface disposed opposite the foot. The portable power supply includes a power source at least partially disposed in the housing and configured to supply power to the outlet. The portable power supply includes a bar pivotably coupled to the housing and configured to pivot about a pivot axis. The housing includes a recess defined therein with the pivot axis extending through the recess. In a storage position, the bar is disposed on a side of the plane in common with the foot. In a standing position, the bar extends away from the foot and intersects the plane.

The present disclosure provides, in another aspect, a portable power supply comprising a housing, an outlet disposed on the housing, a power source at least partially disposed in housing and configured to supply power to the outlet, a frame surrounding the housing, and a handle coupled to the frame. The handle includes a pair of tubes received by the frame and configured to move relative to the frame, a grip extending between the pair of tubes, an actuator received on the grip and configured to translate along an actuator axis, and an elongated rigid member received within a tube of the tubes. The elongated rigid member is configured to move relative to the tube upon actuation of the actuator along the actuator axis. The handle includes a locking assembly having a pin member configured to engage the frame in a locked position. The pin member is configured to retract in response to actuation of the elongated rigid member.

### BRIEF DESCRIPTION OF THE DRAWINGS

FIG. 1 is a perspective view of a portable power supply including a handle in a retracted position.

FIG. 2 a perspective view of the portable power supply of FIG. 1, with the handle in an extended position.

FIG. 3 is an exploded view of the handle of the portable power supply of FIG. 1.

FIG. 4 is a cross section view of a lock assembly of the handle of FIG. 3 in a locked position, taken along section 4-4 in FIG. 3.

FIG. 5 is a perspective view of the lock assembly of FIG. 4 received in a frame of the portable power supply in a locked position.

FIG. 6 is a cross section view of a lock assembly of the handle of FIG. 3 in an unlocked position.

FIG. 7 is a perspective view of the lock assembly of FIG. 6 received in the frame of the portable power supply in an unlocked position.

FIG. 8 is perspective view of a portable power supply according to another construction.

FIG. 9 is a side view of the portable power supply of FIG. 8.

FIG. 10 is a perspective view of a portable power supply according to another construction, having a bar in a standing position.

FIG. 11 is a front view of the portable power supply of FIG. 10 with the bar in the standing position.

FIG. 12 is a cross section view of the bar of the portable power supply of FIG. 10, taken along section 12-12 in FIG. 11.

FIG. 13 is a top view of the portable power supply of FIG. 10 with the bar in the storage position.

FIG. 14 is a front view of a bar, according to another construction.

FIG. 15 is a front view of a bar, according to another construction.

FIG. 16 is a perspective view of a portable power supply according to another construction, with the handle in the extended position.

FIG. 17 is a perspective view of the portable power supply of FIG. 16, with the handle in the retracted position and the bar in the standing position.

FIG. 18 is a top view of the portable power supply of FIG. 16, with the bar in the storage position.

FIG. 19 is a perspective view of the portable power supply of FIG. 16, with the handle in the retracted position and the bar in the storage position.

FIG. 20 is a perspective view of the portable power supply of FIG. 16, with the handle in the retracted position and the bar in the storage position.

FIG. 21 is a rear perspective view of the portable power supply of FIG. 16.

FIG. 22 is a magnified view of a storage compartment of the portable power supply of FIG. 16, with a cover of the storage compartment being open.

FIG. 23 is a perspective view of a cover surrounding the portable power supply of FIG. 16.

FIG. 24 is a top view of the portable power supply of FIG. 16.

FIG. 25 is a front view of the portable power supply of FIG. 16.

FIG. 26 is a side view of the portable power supply of FIG. 16.

FIG. 27 is a side view of the portable power supply of FIG. 16.

FIG. 28 is a perspective view of the portable power supply of FIG. 16, with a 110V female connector.

FIG. 29 is the perspective view of the portable power supply of FIG. 16 with the housing and frame being partially transparent.

FIG. 30 is a side view of the portable power supply of FIG. 16 with the housing and frame being partially transparent.

FIG. 31 is the front view of the portable power supply of FIG. 25 with the housing and frame being partially transparent.

FIG. 32 is a perspective view of the portable power supply of FIG. 16, the portable power supply powering multiple AC power tools.

FIG. 33 is a perspective view of the portable power supply of FIG. 16, the portable power supply powering multiple AC power tools while connected to a power input unit.

FIG. 34 is a cross section view of a lock assembly according to another construction in a locked position.

FIG. 35 is a cross section view of the lock assembly of FIG. 34 in an unlocked position.

Before any constructions of the disclosure are explained in detail, it is to be understood that the disclosure is not limited in its application to the details of construction and the arrangement of components set forth in the following description or illustrated in the following drawings. The disclosure is capable of other constructions and of being practiced or of being carried out in various ways.

### DETAILED DESCRIPTION

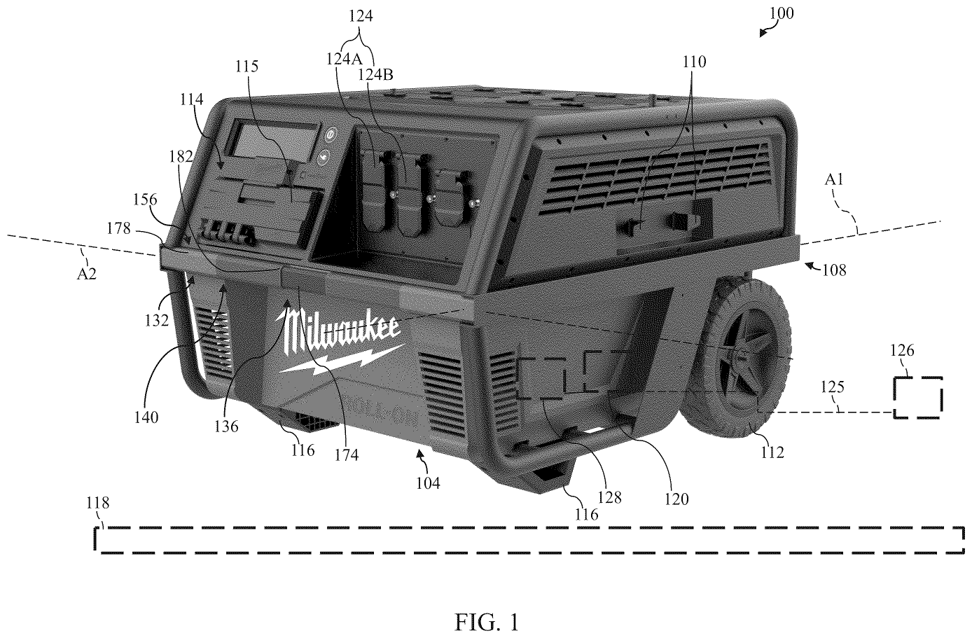

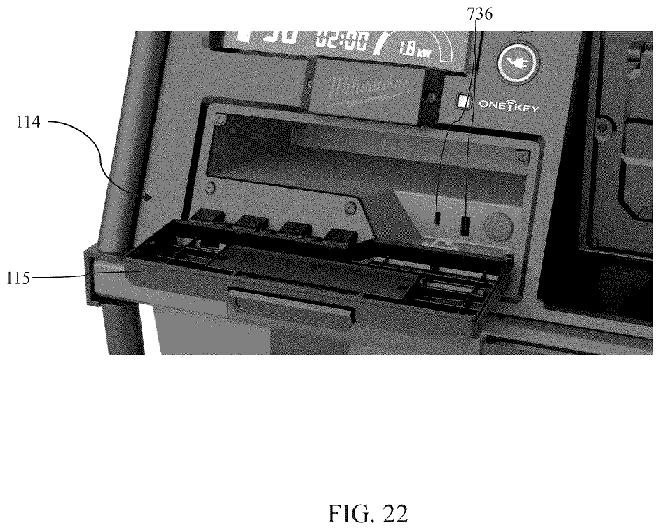

FIG. 1 illustrates a portable power supply 100 including a housing 104 and a frame 108 surrounding the housing 104. The housing 104 includes one or more cord wrap hooks 110. The housing 104 includes one or more wheels 112. In some constructions, the wheels are coupled to the frame 108. The housing 104 includes a storage compartment 114. The storage compartment 114 includes a cover 115 that is biased closed but may be opened to reveal the storage compartment 114 (FIG. 22). The frame 108 includes one or more feet 116 adjacent the wheels 112. The wheels 112 and the feet 116 are configured to engage a support surface 118.

The portable power supply 100 includes a power input unit 120 and an outlet 124. The power input unit 120 includes electrical connection interfaces, such as a cable or power cord 125, configured to receive power from an external power source, such as mains electricity from a wall outlet 126. In some constructions, the external power source is a DC power source. For example, the DC power source may be one or more photovoltaic cells (e.g., a solar panel), an electric vehicle (EV) charging station, or any other DC power source. In some constructions, the external power source is an AC power source. For example, the AC power source may be a conventional wall outlet, such as a 120 V outlet or a 240 V outlet, found in North America. As another example, the AC power source may be a conventional wall outlet, such as a 220V outlet or 230V outlet, found outside of North America. In some constructions, the power input unit 120 further includes one or more devices, such as antennas or induction coils, configured to wirelessly receive power from an external power source. The power received by the power input unit 120 may be used to charge a core battery, or a power source 128, disposed at least partially in the housing 104.

The power received by the power input unit 120 may also be used to provide power to one or more devices connected to the outlet 124. The outlet 124 includes one more power outlets. In the illustrated construction, the outlet 124 includes a plurality of AC power outlets 124A and DC power outlets 124B. It should be understood that number of power outlets included in the outlet 124 is not limited to the power outlets illustrated in FIG. 1. For example, in some constructions of the power supply 100, the outlet 124 may include more or fewer power outlets than the power outlets included in the illustrated construction of power supply 100. In some constructions, the outlet includes two 20 A duplexes and one 30 A outlet.

In some constructions, the outlet 124 is configured to provide power output by the power source 128 to one or more peripheral devices. In some constructions, the outlet 124 is configured to provide power provided by an external power source directly to one or more peripheral device. The one or more peripheral devices may be a smartphone, a tablet computer, a laptop computer, a portable music player, a power tool, a power tool battery pack, a power tool battery pack charger, or the like. The peripheral devices may be configured to receive DC and/or AC power from the outlet 124.

The portable power supply 100 includes a handle 132. FIG. 1 illustrates the handle 132 coupled to the frame 108 in a retracted position. In other constructions, the handle 132 is coupled to the housing 104. In other words, the handle 132 is compatible with the housing 104. However, for the sake of simplicity, the interface between the frame 108 and the handle 132 is only discussed. The handle 132 includes an actuator 136 received by a grip 140 of the handle 132.

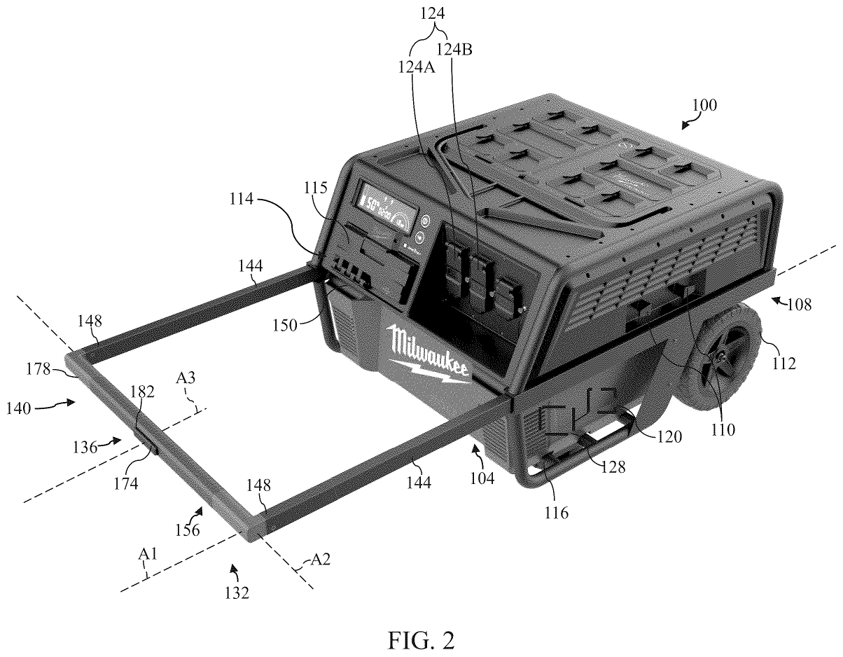

FIG. 2 illustrates the handle 132 having one or more tubes 144 coupled to the grip 140 at one end 148. The housing 104 includes a recess 150 configured to receive the handle 132 when in the retracted position (FIG. 1). In the illustrated construction, the handle 132 is a telescoping handle. The tubes 144 are received by the frame 108 and are slidable relative to the frame 108. FIG. 2 illustrates the handle 132 an extended position. From the retracted position (FIG. 1) to the extended position, the handle 132 is axially moveable along a longitudinal axis A1 defined by the portion of the frame 108 receiving the handle 132. Specifically, in the extended position, the grip 140 is disposed at an axial position on the longitudinal axis A1 at a location furthest from the frame 108.

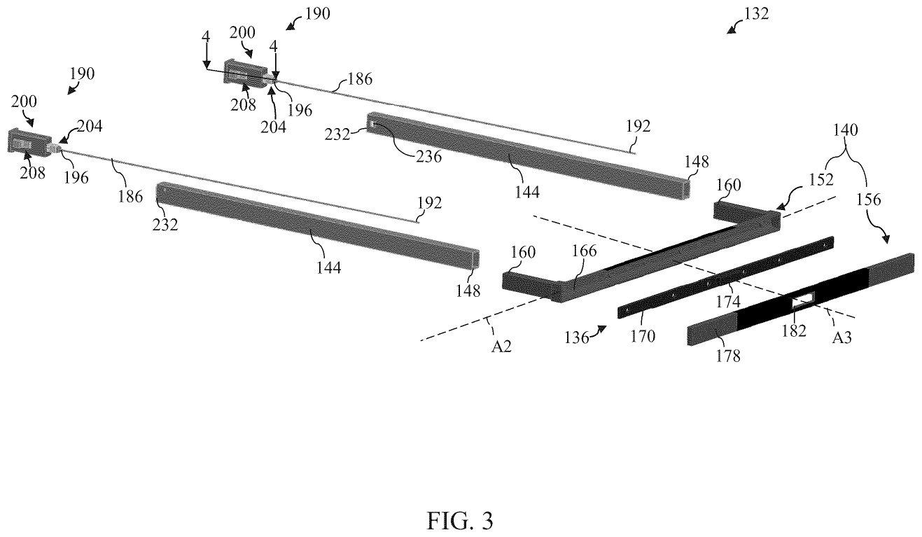

FIG. 3 illustrates an exploded view of the handle 132. The grip 140 is comprised of a main body 152 and a cover 156. In the illustrated construction, the main body 152 extends between the tubes 144. The main body 152 includes one or more hollow ends 160 having a corresponding shape to the ends 148 of the tubes 144. Specifically, the ends 160 of the main body 152 are sized nominally smaller than the ends 148 of the tubes 144 such that the body 152 is received within the tubes 144 (e.g., the ends 160 are received within the ends 148). In other constructions, the tubes 144 are received within the body 152 (e.g., the ends 148 are received within the ends 160). In the illustrated construction, the body 152 includes a recess 166 extending into the body 152 in a direction parallel to the axis A1 and between the tubes 144. The recess 166 extends for a majority of a length of the grip 140 measured along a grip axis A2 that is transverse (e.g., perpendicular) to the axis A1. The recess 166 axially overlaps with at least one of the ends 160 along the longitudinal axis A1 such that a passage extends between the tubes 144 and the grip 140. The recess 166 is configured to receive the actuator 136.

The actuator 136 includes a main body 170 and a projection 174. In the illustrated construction, the main body 170 extends for a majority of the length of the recess 166 such that a portion of the main body 170 axially overlaps with one of the ends 160 along the longitudinal axis A1. In some constructions, the main body 170 extends along the entire length of the grip 140 along the grip axis A2. The projection 174 extends outwardly from the main body 170 in a direction parallel to the longitudinal axis A1. In the illustrated construction, the projection 174 is centrally located on the main body 170. In other words, the projection 174 is located on the main body 170 at a midpoint between the ends 160. The actuator 136 is configured for displacement upon actuation of the actuator 136 by a user. In the illustrated construction, the actuator 136 is slidable along an actuator axis A3 that is parallel to the longitudinal axis A1.

The cover 156 encloses the recess 166 with the actuator 136 disposed therein. The cover 156 includes a main body 178 and an aperture 182. The main body 178 extends for the majority of the length of the grip 140 measured along a grip axis A2 that is transverse (e.g., perpendicular) to the axis A1. In some constructions, the main body 178 fully covers the recess 166. The projection 174 of the actuator 136 is received within the aperture 182 of the cover 156 and extends through the aperture 182. The projection 174 is accommodated such that a user may actuate the actuator 136 through the aperture 182.

The handle 132 includes one or more elongated rigid members 186 and a lock assembly 190. The rigid members 186 are moveably received within the tubes 144 and the main body 152. Specifically, an end 192 of the rigid member 186 is coupled to the main body 170 of the actuator 136 through the passage between the tubes 144 and the body 152 (e.g., the tubes 144 and the body 152 are hollow at ends 148, 160, respectively). As such, the rigid members 186 are moveable along the longitudinal axis A1 upon actuation of the actuator 136 along the actuator axis A3. At least one of the rigid members 186 is coupled to the lock assembly 190 at another end 196 opposite the end 192. The lock assembly 190 includes a lock housing 200, a wedge member 204, and a pin member 208.

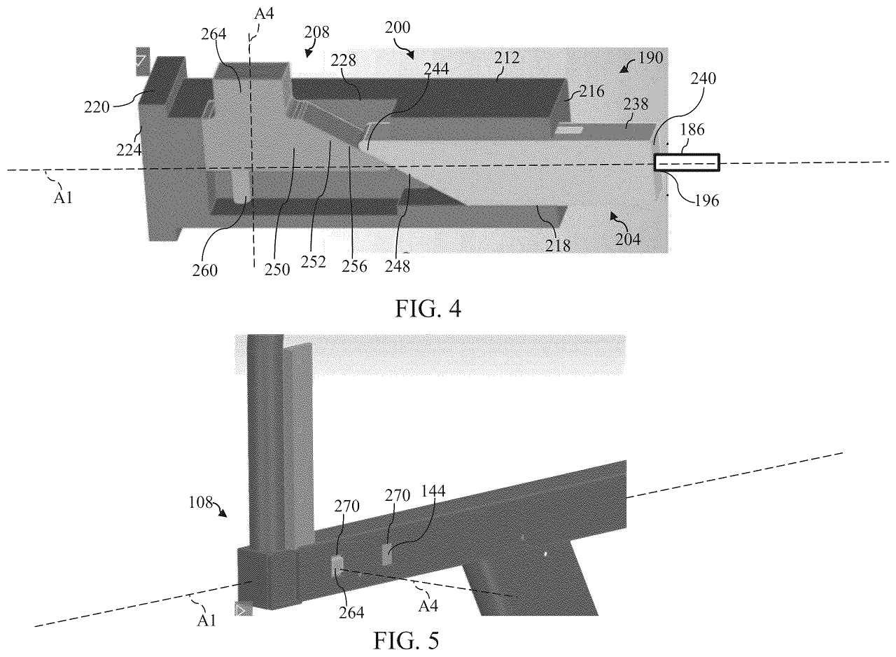

FIG. 4 illustrates the lock housing 200 including a main body 212 having a first lock housing end 216 with an aperture 218 to slidably receive the wedge member 204 (FIG. 4). The main body 212 includes a collar 220 at a second lock housing end 224 opposite the first lock housing end 216. The collar 220 includes a greater width and height relative to the main body 212. The main body 212 includes an aperture 228 defined in the lock housing between the first and second lock housing ends 216, 224. The main body 212 slidable receives the pin member 208 in the aperture 228. The main body 212 includes a shape corresponding to the tubes 144 from the first lock housing end 216 up to the collar 220 such that the lock housing 200 is received within an end 232 of the tubes 144. The end 232 is opposite the end 148. Other than the collar 220, the main body 212 is sized nominally smaller than the tubes 144 such that the lock housing 200 is received in the tubes 144. The collar 220 prevents over insertion of the main body 212 along the longitudinal axis A1 due to the greater width and height than the interior of the tubes 144. In other words, the collar 220 axially locates the main body 212 along the longitudinal axis A1. In the illustrated construction, at least one of the tubes 144 includes an aperture 236 defined therein disposed near to the end 232. Upon complete insertion of the lock housing 200 into the tubes 144, the aperture 228 of the main body 212 and the aperture 236 of the tubes 144 axially overlap along the longitudinal axis A1.

FIG. 4 illustrates the wedge member 204 including a main body 238 with a wedge end 240 and another wedge end 244 opposite the wedge end 240, the other wedge end 244 having a slanted wall 248. The elongated rigid member 186 is coupled to the wedge member 204 and extends away from the wedge end 240. The pin member 208 includes a main body 250 with a pin end 252 having a corresponding slanted wall 256 that engages the slanted wall 248. In other words, the pin end 252 is complementary to the other wedge end 244 such that the slanted walls 248, 256 engage each other. The lock assembly 190 includes a bias 260 (e.g., a spring) for urging the pin member 208 along a locking axis A4. The bias 260 is disposed between the lock housing 200 and the pin member 208. In the illustrated construction, the locking axis A4 is transverse (e.g., perpendicular) to the longitudinal axis A1 and is parallel to the grip axis A2. The pin member 208 includes a pin 264 extending from the main body 250 in a direction along the locking axis A4. The pin 264 is disposed on a wall opposite from where the bias 260 engages the main body 250.

The wedge member 204 is moveable along the longitudinal axis A1 upon actuation of the actuator 136 or engagement of the pin member 208 due to the bias 260. The pin member 208 is moveable along the locking axis A4 upon engagement of the wedge member 204 or biasing movement from the bias 260. The wedge member 204 is constrained to axial movement along the longitudinal axis A1 and the pin member 208 is constrained to axial movement along the locking axis A4, which is transverse (e.g., perpendicular) to the longitudinal axis A1.

FIG. 5 illustrates the handle 132 received within the frame 108 with the housing 104 hidden. The frame 108 includes one or more apertures 270 defined therein. The apertures of the apertures 270 are axially spaced along the longitudinal axis such that the handle 132 is adjustable along the longitudinal axis A1.

FIGS. 4 and 5 illustrate the lock assembly 190 in a locked position. In the locked position, the bias 260 biases the pin member 208 along the lock axis A4 such that the pin 264 protrudes from the lock housing 200, the tubes 144, and into contact with the frame 108. In other words, the pin 264 extends through the apertures 228, 236, 270 of the main body 212, the tubes 144, and the frame 108, respectively, such that the pin 264 engages the frame 108. Specifically, the pin 264 engages the aperture 270. In the locked position, the apertures 228, 236, 270 axially overlap along the longitudinal axis A1. In the locked position, the end 240 of the wedge member 204 is located furthest from the collar 220 along the longitudinal axis A1.

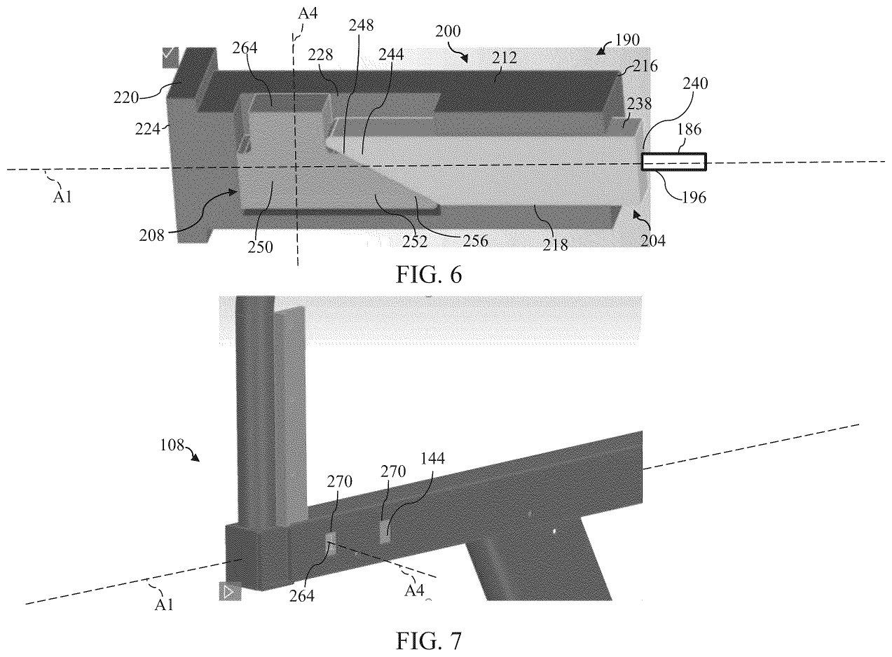

FIGS. 6 and 7 illustrate the lock assembly 190 in an unlocked position. To get to the unlocked position from the locked position (FIGS. 4-5), the actuator 136 is displaced along the actuator axis A3. The rigid member 186 is displaced along the longitudinal axis A1 since the rigid member 186 is coupled to the actuator 136 for movement therewith. The wedge member 204 is axially displaced along the longitudinal ais A1 since the wedge member 204 is coupled to the rigid member 186 for movement therewith. As the wedge member 204 is axially displaced along the longitudinal axis A1, the slanted wall 248 engages the corresponding slanted wall 256 of the pin member 208 (e.g., the wedge member 204 is displaced along the longitudinal axis A1 toward the collar 220). As such, the pin member 208 is axially displaced along the locking axis A4 against the biasing force of the bias 260 in response to axial displacement of the wedge member 204 toward the collar 220. The pin 264 is retracted further into the lock housing 200 in response to the pin member 208 being axially displaced along the locking axis A4. The unlocked position is a position in which the pin 264 is received far enough in the lock housing 200 such that the pin 264 does not engage the frame 108 (e.g., the pin 264 being recessed relative to the frame aperture 270). For instance, in the unlocked position, the pin 264 is flush with the body 212 of the lock housing 200.

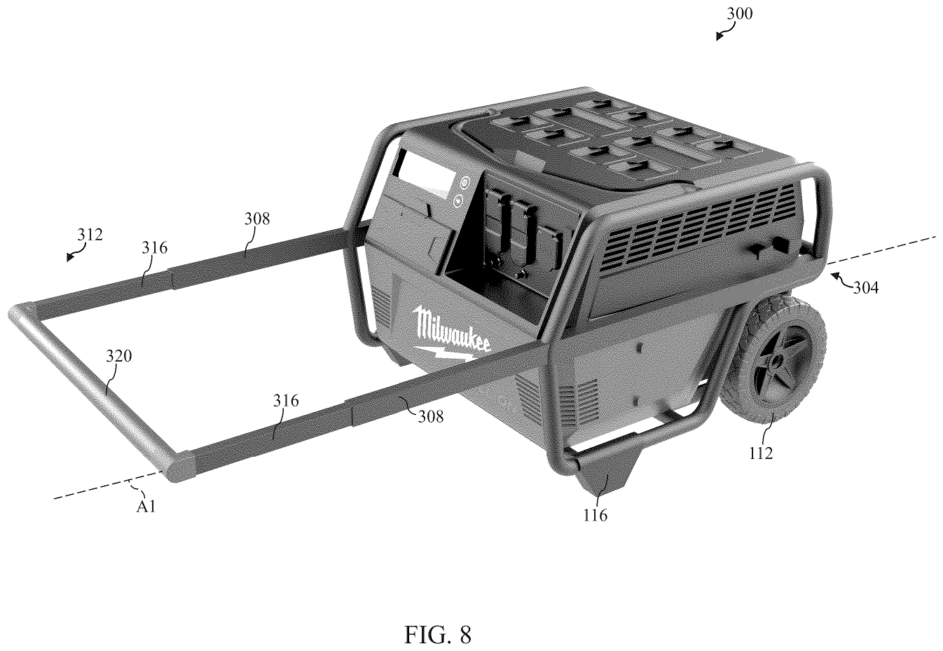

FIG. 8 illustrates another construction of a portable power supply 300. The portable power supply 300 is similar to the portable power supply 100 and therefore only differences will be discussed. The portable power supply 300 includes a frame 304 having a one or more longitudinal tubes 308 fixed to the frame 304. In the illustrated construction, the tubes 308 extend from the frame 304 in a direction parallel to the longitudinal axis A1. Specifically, the tubes 308 are fixed to a middle portion of the frame 304. The middle portion of the frame is disposed between a side of the power supply 300 having the wheels 112 and the feet 116 and a side opposite the side with the wheels 112 and feet 116. The portable power supply 300 includes a handle 312 that is received by the longitudinal tubes 308. In other constructions, the handle 312 is interchangeable with the handle 132. In the illustrated construction, the handle 312 includes one or more tubes 316 and a grip 320 coupled to the tubes 316. In the illustrated construction, the handle 312 is a telescopic handle. The handle 312 is displaceable along the longitudinal axis A1. The handle 312 is moveable between the retracted position and the extended position.

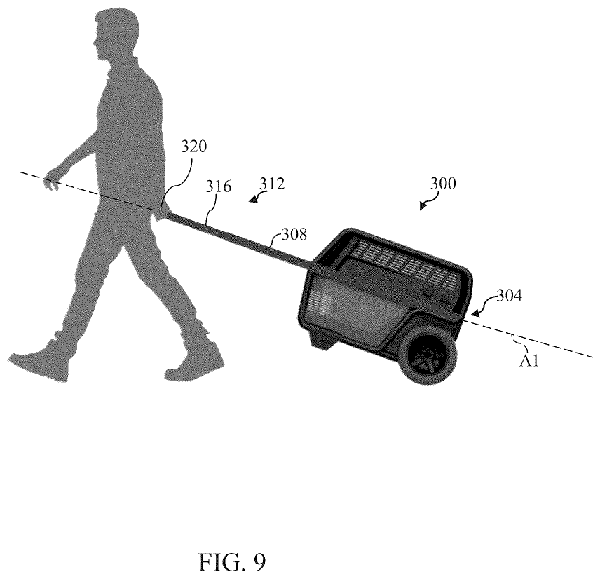

FIG. 9 illustrates the handle 312 in the extended position such that the grip 320 is disposed at a position on the longitudinal axis A1 furthest from the frame 304. The handle 312 is prevented from being displaced too far along the longitudinal axis by set screws configured to engage the frame 304 or the tubes 308. The handle 312 provides additional length along the longitudinal axis A1 due to the longitudinal tubes 308, in contrast to the handle 132. The additional length along the longitudinal axis A1 increases leverage for transporting the portable power supply 300. Additionally, the length prevents incidental contact from user during transport (e.g., heels hitting the portable power supply 300).

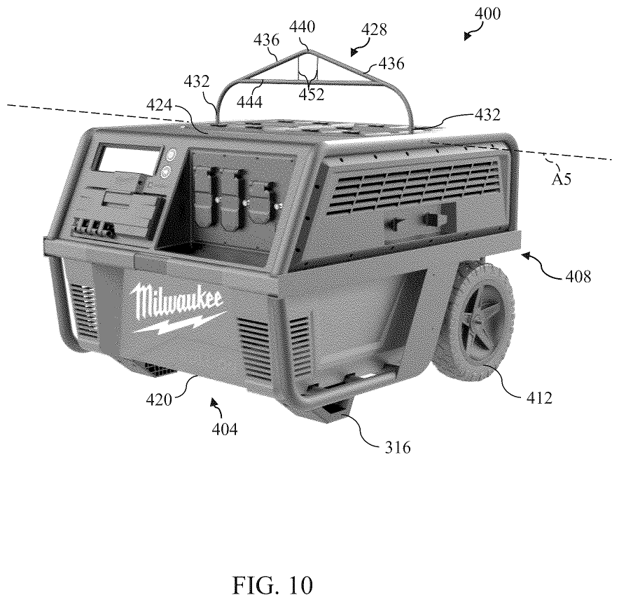

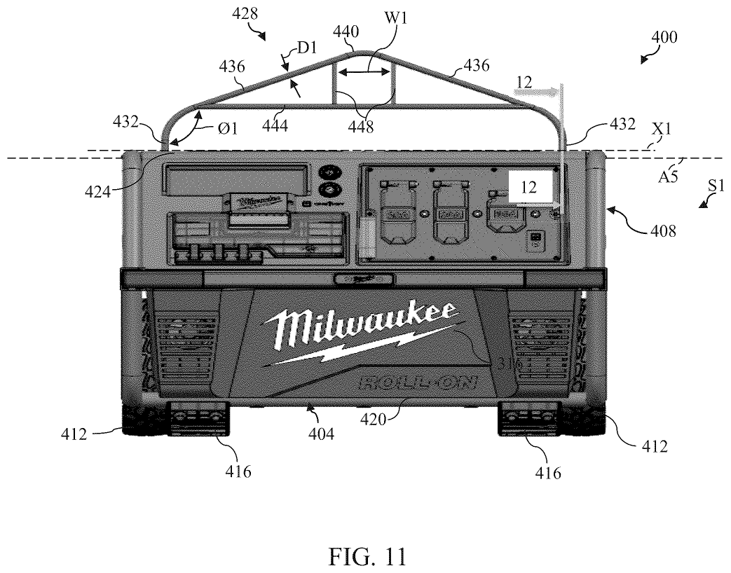

FIG. 10 illustrates another construction of a portable power supply 400. The portable power supply is similar to the portable power supply 100 and therefore only differences will be discussed. The portable power supply 400 includes a housing 404 and a frame 408 surrounding the housing 404. The housing 404 includes one or more wheels 412. In some constructions, the wheels are coupled to the frame 408. The frame 408 includes one or more feet 416 adjacent the wheels 412. The housing 404 includes a lower surface 420 near to the wheels 412 and the feet 416 and an upper surface 424 opposite the lower surface 420. The upper surface 424 partially defines a plane X1 (FIG. 11).

The portable power supply 400 includes a bar 428 pivotably coupled to the housing 404. The bar 428 is a pivoting hoist bar. In other words, the bar 428 is capable of supporting the weight of the portable power supply 400 in the instance that the bar 428 is used as a lift point to lift the power supply 400. In some constructions, the bar 428 is rated to hold 800 lbf and maintain a 195 MPa yield stress. In the illustrated construction, the bar 428 is constructed of #45 steel. In the illustrated construction, the bar 428 weighs between 1 kg and 2 kg. Specifically, in the illustrated construction, the bar 428 weights 1.15 kg. The bar 428 is coupled to the housing 404 near to the upper surface 424. In other constructions, the bar 428 is coupled to the frame 408. The bar 428 is compatible with the portable power supplies 100, 300.

FIG. 11 illustrates the bar 428 includes a pair of parallel segments 432 that are coupled to the housing 404. In the illustrated construction, the bar 428 is a solid bar. In some constructed, the bar 428 is a hollow bar. In the illustrated construction, the bar 428 defines a diameter D1. In some constructions, the diameter D1 is less than 20 millimeters. In the illustrated construction, the diameter D1 is 13 millimeters. The bar 428 includes a pair of angled segments 436 coupled to the pair of the parallel segments 432. Each of the angled segments 436 are offset from a respective segment of the pair of parallel segments 432 at a non-zero angle Ø1. In the illustrated construction, the non-zero angle Ø1 is less than 180 degrees. Specifically, the non-zero angle Ø1 is 112 degrees. The angled segments 436 meet in a middle of the bar 428 and are joined together at an apex 440. The bar 428 includes a horizontal segment 444 that is transverse (e.g., perpendicular) to the pair of parallel segments 432. The horizontal segment 444 extends between the pair of angled segments 436. The bar 428 includes a pair of segments 448 extending between the horizontal segment 444 to the pair of angled segments 436. In the illustrated construction, the pair of segments 448 are parallel with one another and defined a width W1. In the illustrated construction, the width W1 is at least 2 inches such that a 2-inch rigging strap is received between the segments 448. In the illustrated construction, the pair of segments 448 are parallel to the pair of parallel segments 432.

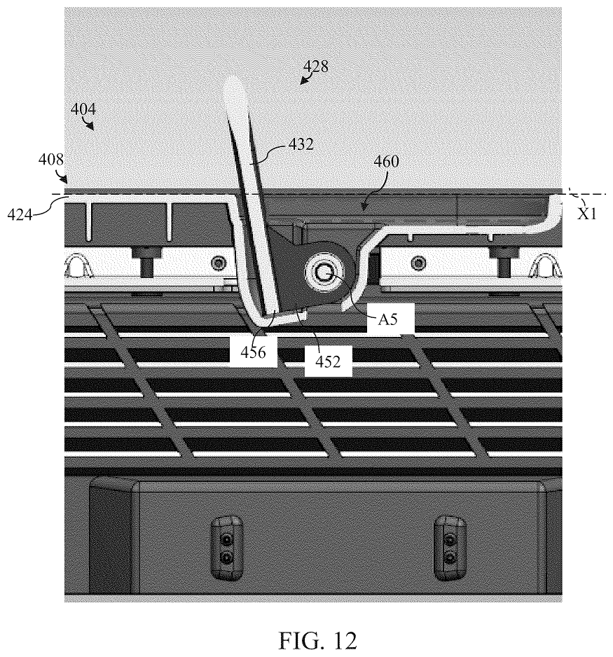

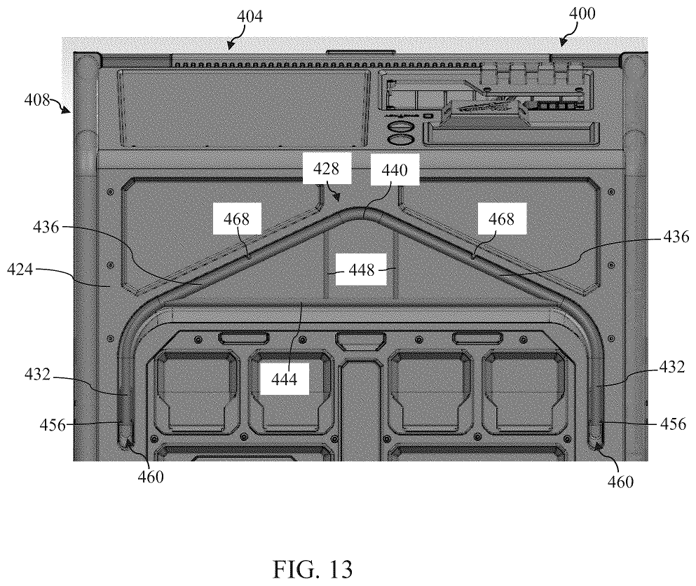

FIG. 12 illustrate a segment of the pair of parallel segments 432 pivotably coupled to the housing 404 such that the bar 428 pivots about a pivot axis A5. In the illustrated construction, the bar 428 includes a flange 452 disposed near an end 456 of the bar 428. The housing 404 incudes a recess 460 that is defined in the housing 404. Specifically, the recess 460 extends from the upper surface 424 and toward the lower surface 420. The pivot axis A5 extends through the recess 460. The bar is moveable between a standing position (FIGS. 10-12) and a storage position (FIG. 13).

FIGS. 10-12 illustrate the bar 428 in the standing position. The bar 428 extends away from the lower surface 420 and intersects the plane X1 in the standing position. The end 456 of the bar 428 is configured to engage the housing 404 in the recess 460 in the standing position. In the standing position, the bar 428 maintains position without external forces (e.g., biasing forces, interference fits, etc.). As such, the pivot movement between the standing position and the storage position is without the stiff movement that would be caused by biasing forces or interference fits.

FIG. 13 illustrates the bar 428 in the storage position. The housing 404 includes protrusions 468 that engage the bar 428. In the illustrated construction, the protrusions 468 extend into the recess 460 such that the bar 428 is retained in the recess 460. In the storage position, the bar 428 is disposed on a side S1 of the plane X1 that has the wheels 412 and the feet 416. In the storage position, the bar 428 does not intersect the plane X1 (schematically illustrated in FIG. 12). In other words, the bar 428 is disposed below the upper surface 424 in the storage position.

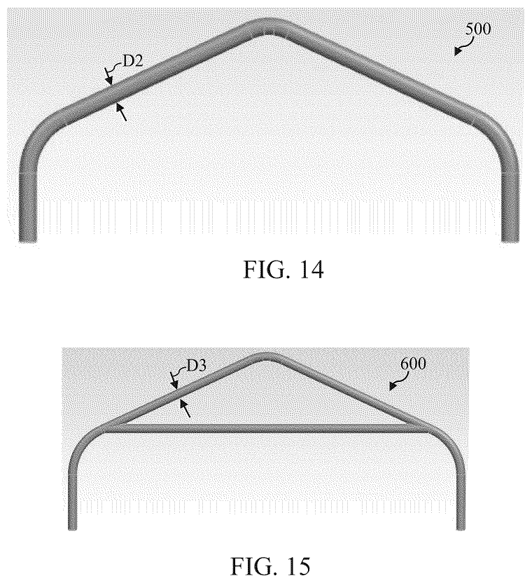

FIG. 14 illustrates another construction of a bar 500. The bar 500 is interchangeable with the bar 428. The bar 500 is similar to the bar 428 and therefore only differences will be discussed. The bar 500 does not include the horizontal segment 444 or the segments 448. The bar 500 defines a diameter D2. In the illustrated construction, the diameter D2 is 19 millimeters and weighs approximately 1.78 kg.

FIG. 15 illustrates another construction of a bar 600. The bar 600 is interchangeable with the bar 428. The bar 600 is similar to the bar 428 and therefore only differences will be discussed. The bar 600 does not include the segments 448. The bar 600 defines a diameter D3. In the illustrated construction, the diameter D3 is 12 millimeters and weighs approximately 1.12 kg.

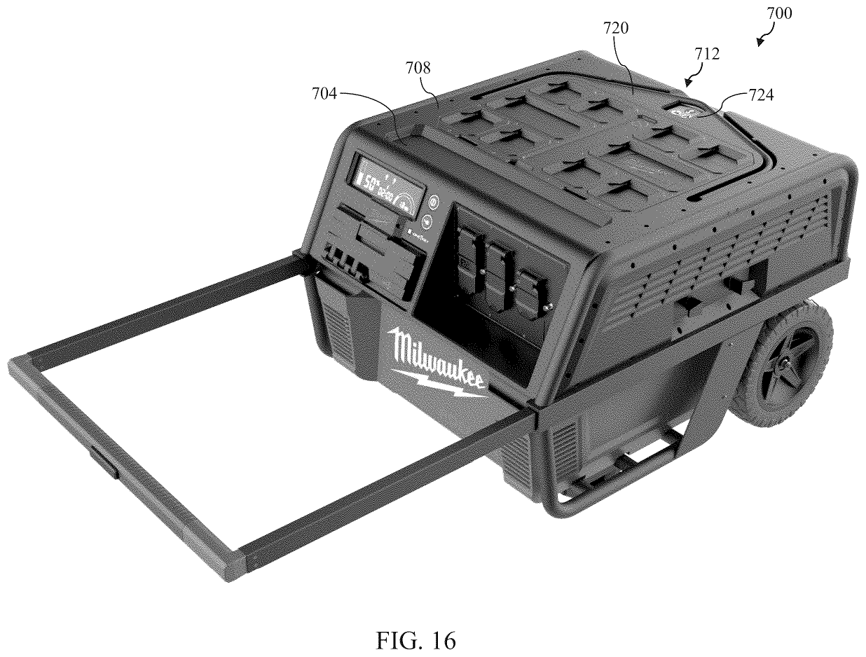

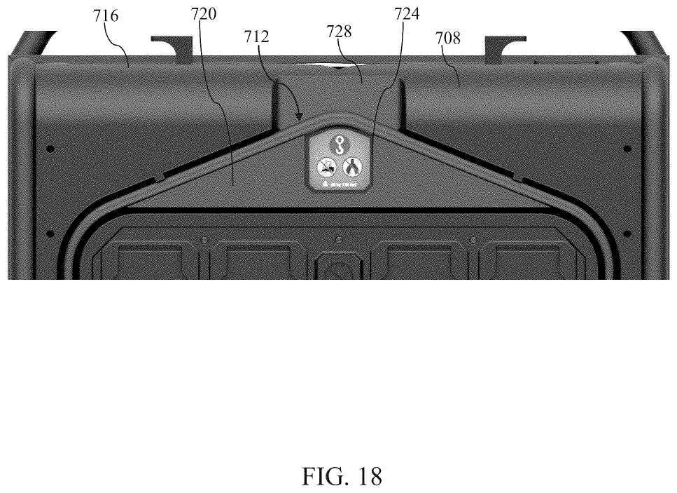

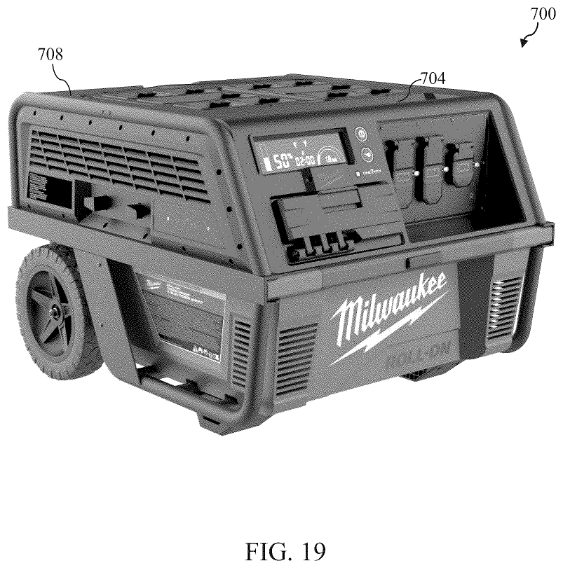

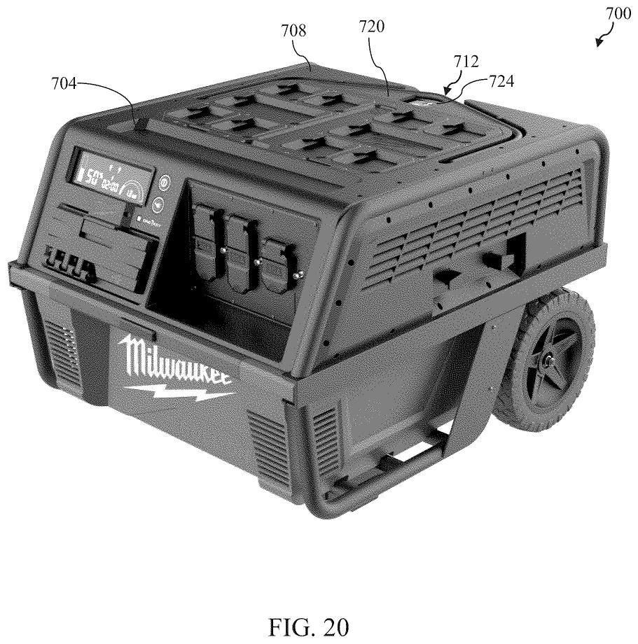

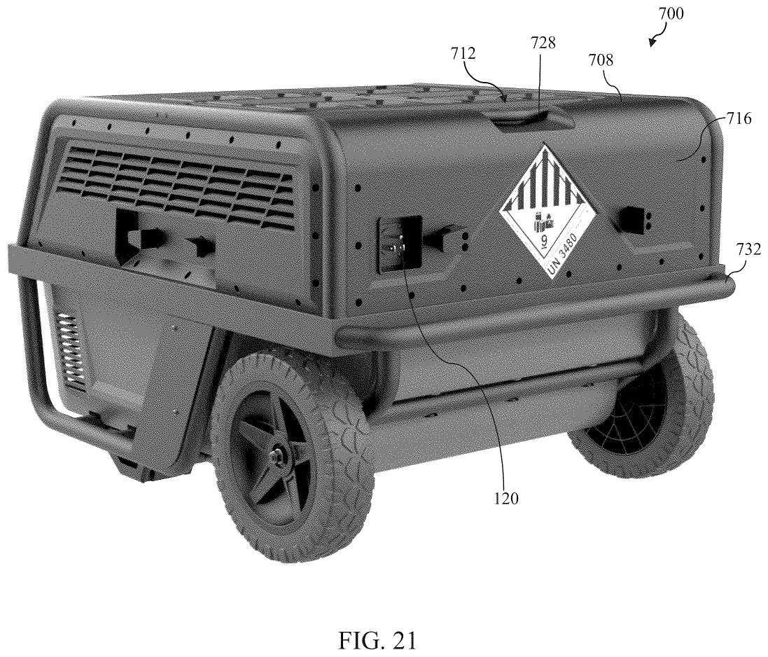

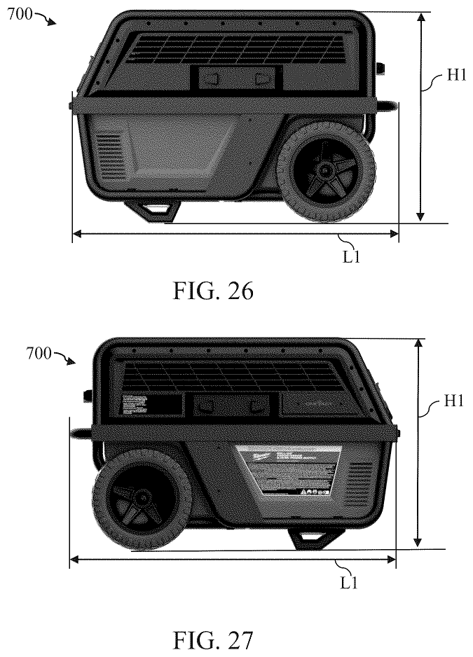

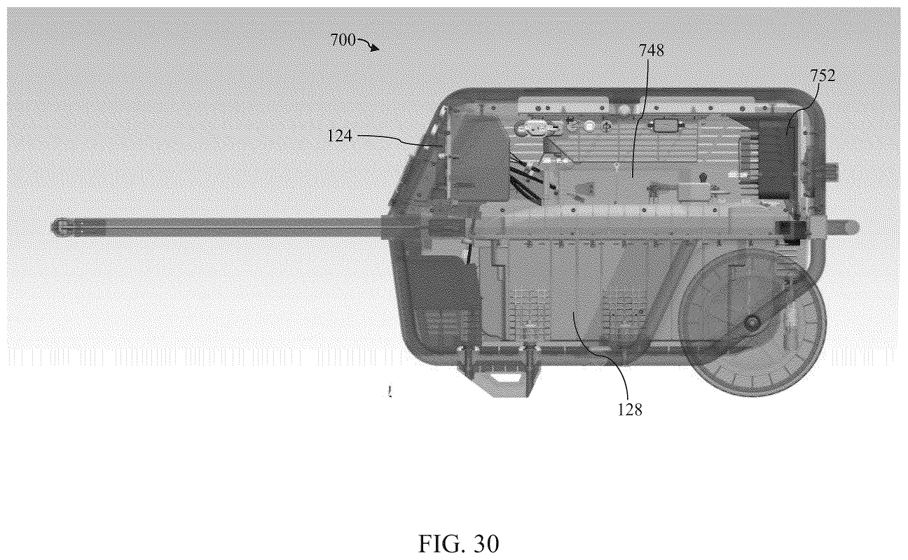

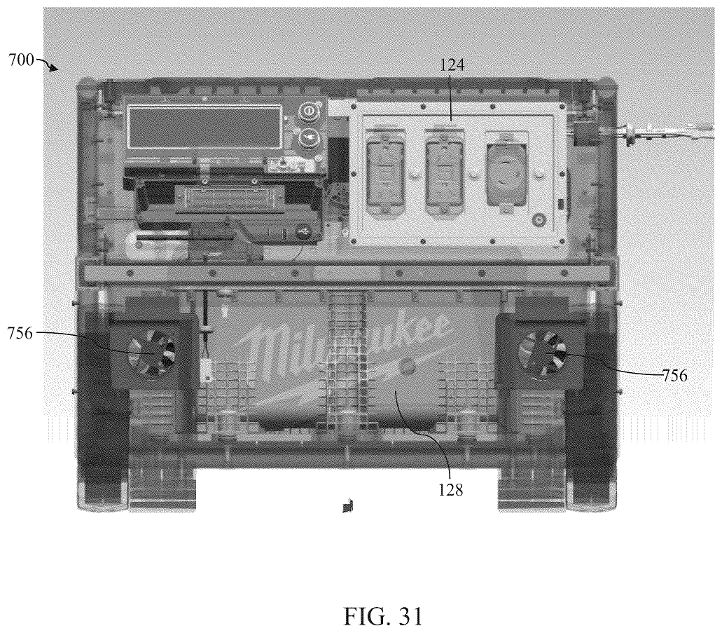

FIGS. 16-33 illustrate a portable power supply 700 according to another construction. The portable power supply 700 is similar to the portable power supply 100 and therefore only differences will be discussed. Referring to FIG. 16, the portable power supply 700 includes a recess 704 on an upper surface 708. In the illustrated construction, the recess 704 is sized to accommodate loose fasteners and small tools for temporary storage. The portable power supply 700 includes a bar 712 that is received in the upper surface 708. The bar 712 is interchangeable with the bars 428, 500, and 600. The bar 712 is compatible with the portable power supplies 100, 300, 400. In contrast to the portable power supplies 100, 300, 400, the bar 712 is stored near to a rear wall 716 in the upper surface 708 (FIGS. 18 and 21).

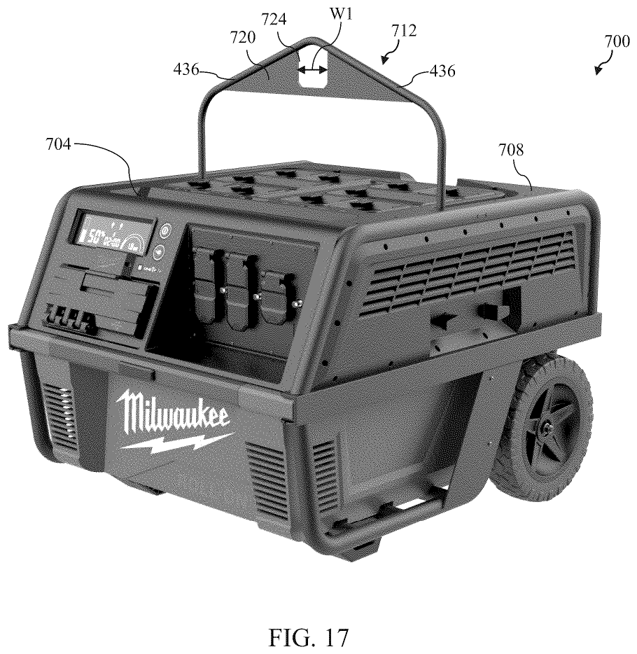

FIG. 17 illustrates the bar 712 including a skirt 720 extending between the angled segments 436. The skirt 720 includes an opening 724 such that the opening 724 maintains the width W1 to receive a 2-inch rigging strap.

FIG. 18 illustrates the upper surface 708 including a recess 728 enabling access to the bar 712 when the bar 712 is in the storage position. In the illustrated construction, the recess 728 extends from the bar 712 to the rear wall 716.

FIG. 21 illustrates the frame 108 including a rear grab bar 732. The bar 732 may be used for repositioning the portable power supply 700. In the illustrated construction, the power input unit 120 of the portable power supply 700 is an AC inlet.

FIG. 22 illustrates the cover 115 being open to reveal the storage compartment 114. The storage compartment 114 is sized to accommodate a phone. Additionally, in the illustrated construction, the storage compartment 114 includes charging ports 736. Specifically, the ports 736 are common outlets for phones (e.g., USB-C, USB-A, etc.).

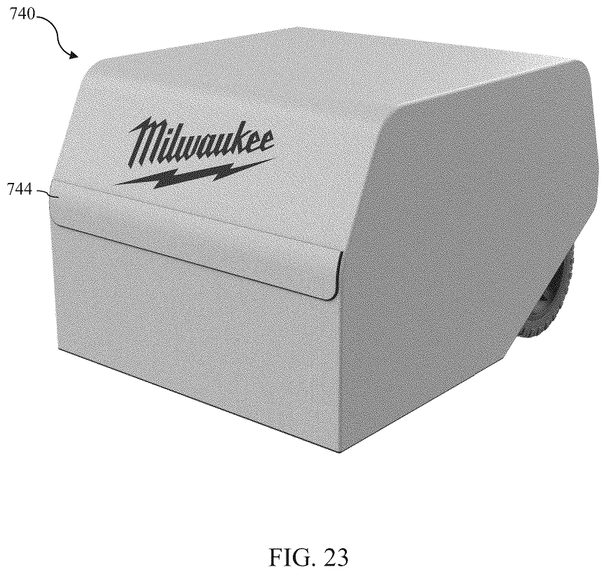

FIG. 23 illustrates a cover 740 that is compatible with the portable power supply 700. The cover 740 is waterproof and repels water from the portable power supply 700. The cover 740 mostly covers the portable power supply 700, except for the wheels 112. The cover 740 includes an access flap 744 positioned on the cover 740 to correspond with the handle 132. When the access flap 744 is pivoted from the cover 740, the handle 132 will be exposed to the user. The user may extend the handle 132 through the cover 740 by extending the handle 132 through a space that us defined by opening the access flap 744.

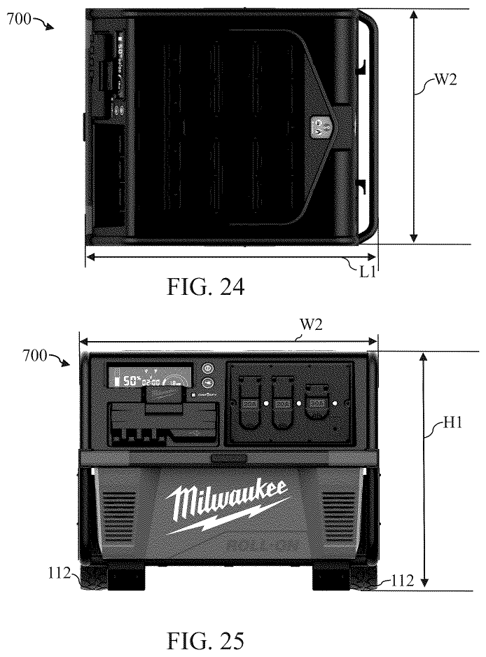

FIGS. 24-27 illustrate the dimensions of the portable power supply 700. The power supply 700 defines a width W2. Specifically, the housing 104 and the frame 108 define the width W2. In some constructions, the width is less than 30 inches. In the illustrated construction, the width W2 is approximately 25 inches. The width W2 of the portable power supply 700 is sized to permit the portable power supply 700 to be wheeled through a common doorway dimension (e.g., W2 is less than 30 inches). In the illustrated construction, the wheels 112 are disposed within a maximum width (e.g., the width W2) of the portable power supply 700. The portable power supply 700 defines a height H1 and a length L1. In some constructions, the height H1 is less than 25 inches. In the illustrated construction, the height H1 is approximately 19 inches. The height H1 of the portable power supply 700 is sized to permit the portable power supply 700 to fit under a tonneau cover in a truck bed (e.g., H1 is less than 20 inches). In some constructions, the length L1 is less than 35 inches. In the illustrated construction, the length L1 is approximately 30 inches.

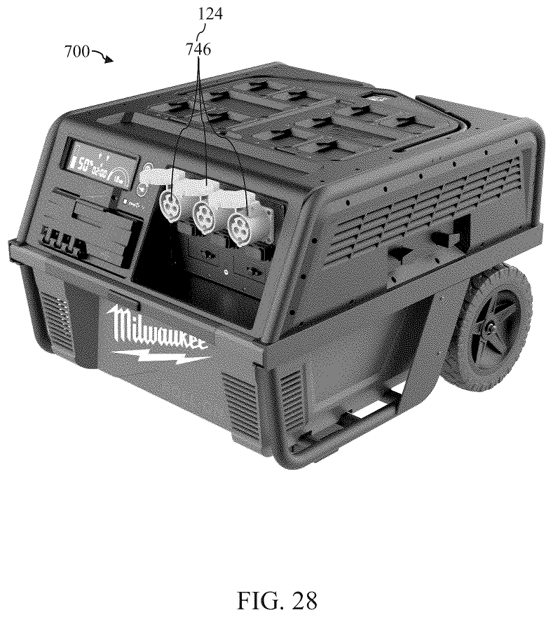

FIG. 28 illustrates the outlets 124 being compatible with 110V female connectors 746. In other constructions, the outlets 124 are interchangeable with other connectors.

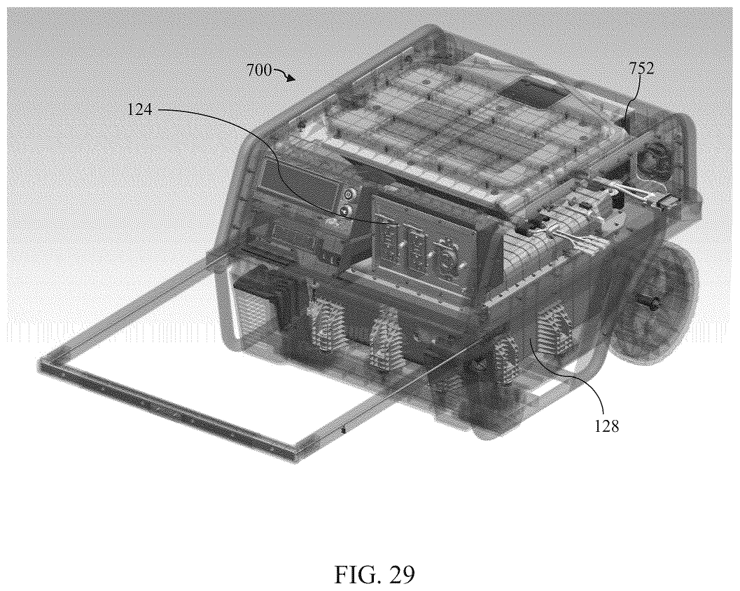

FIGS. 29-31 illustrate the portable power supply 700 with components partially transparent (e.g., the housing 104, the frame 108, etc.). The portable power supply 700 includes the power source 128, an inverter 748, a charger 752, and fans 756 supported in the housing 104. The portable power supply 700 is supplied with outside power through the power input unit 120. The power source 128 provides power to the outlet 124 via the inverter 748 when the portable power supply 700 is not connected to the power input unit 120. In instances when the portable power supply 700 is coupled to the power input unit 120, power from the power input unit 120 may be routed to the outlet 124 to avoid unnecessary draining of the power source 128. The fans 756 are positioned in the housing 104 such that air moves across the inverter 748, the charger 752, and/or the power source 128 to remove heat. In the illustrated construction, a majority of the power source 128 is disposed in the housing 104 nearer to the feet 116 than the bar 712.

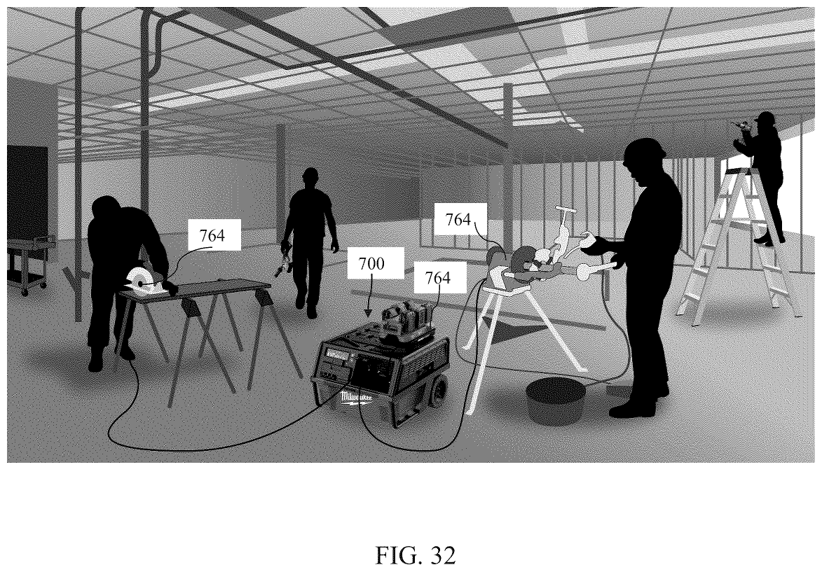

FIG. 32 illustrates the portable power supply 700 supplying power to multiple AC powered devices 764 (e.g., AC tools and battery chargers) without being supplied power from the power input unit 120. In other words, the portable power supply 700 is supplying power to the multiple AC powered devices 764 via the power source 128.

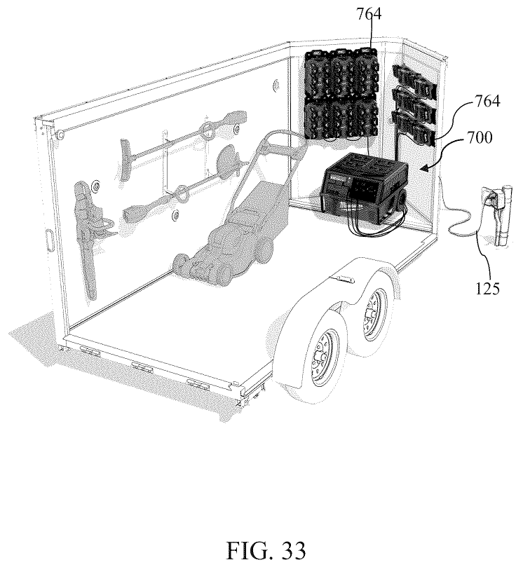

FIG. 33 illustrates the portable power supply 700 supplying power to the multiple AC powered devices 764 while the power input unit 120 is supplied with power from the power cord 125. The power from the power input unit 120 is being routed to the multiple AC powered devices 764. The portable power supply 700 functions as a hub for charging when the portable power supply 700 is connected to the power input unit 120.

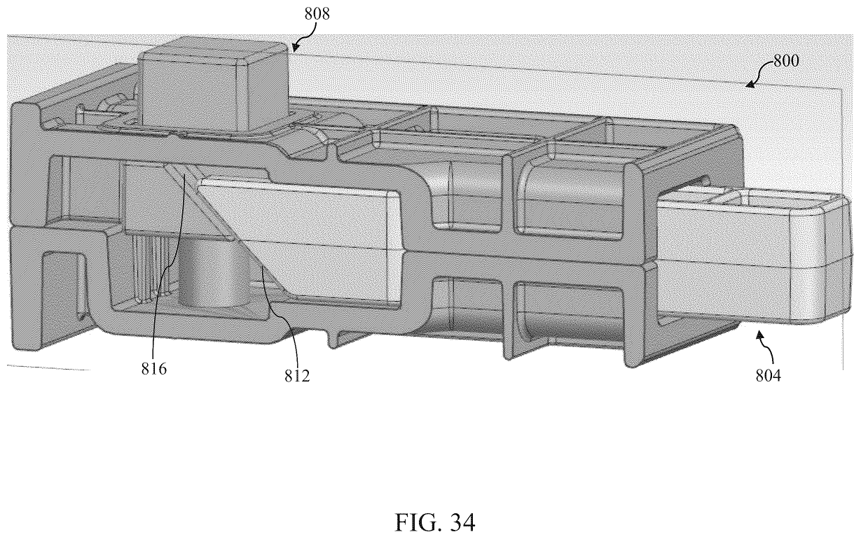

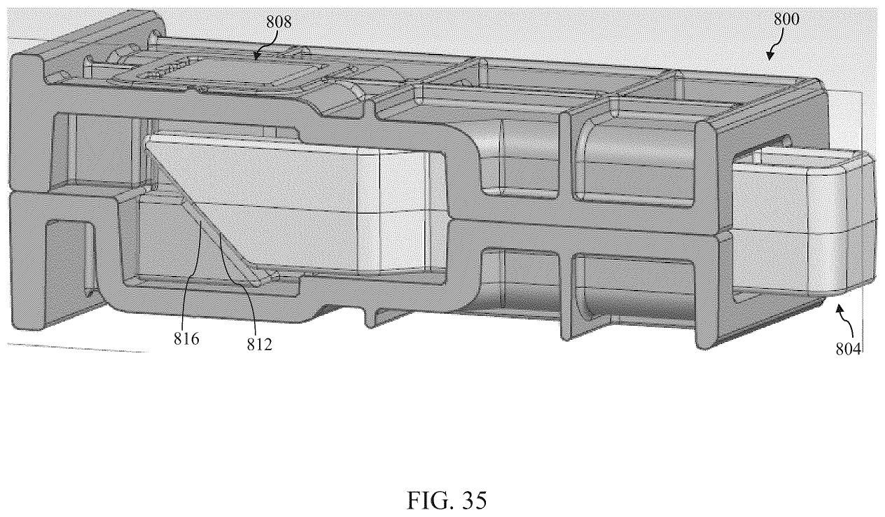

FIGS. 34 and 35 illustrate a lock assembly 800 according to another construction for use with the portable power supplies 100, 300, 400, and 700. The lock assembly 800 is interchangeable with the lock assembly 190. The lock assembly 800 is similar to the lock assembly 190 and therefore only differences will be discussed. FIG. 34 illustrates the lock assembly 800 being in a locked position and FIG. 35 illustrates the lock assembly 800 in the unlocked position.

The lock assembly 800 includes a wedge member 804 and a pin member 808. Instead of the wedge member 804 including an entire end being slanted like the wedge member 204, only a portion of the end of the wedge member 804 includes a slanted wall 812. The pin member 808 includes a corresponding slanted wall 816. As shown in FIGS. 34 and 35, the slanted wall 812 is only a portion of the end of the pin member 808. In some constructions, the wedge member 804 is forked shaped. That is, the wedge member 804 includes another slanted wall (not shown) disposed on the other side of the wedge member 804 to form the fork shape. The pin member 808 includes another corresponding slanted wall (not shown) that mates with the other slanted wall of the wedge member 804.

Although the disclosure has been described in detail with reference to certain preferred constructions, variations and modifications exist within the scope and spirit of one or more independent aspects of the disclosure as described.

What is claimed is:

1. A portable power supply comprising:
a housing;
a power source at least partially disposed in the housing, the power source configured to supply power to at least one outlet disposed on the housing;
a frame surrounding the housing; and
a handle coupled to the frame, the handle including
a grip,
an actuator disposed on the grip and configured for displacement upon actuation of the actuator,
a tube slidable relative to the frame, the tube coupled to the grip at one end,
an elongated rigid member disposed in the tube, the elongated rigid member configured to move along the tube upon actuation of the actuator, and
a lock assembly including a lock housing, a wedge member, and a pin member, the wedge member and the pin member received in the lock housing, the wedge member being coupled to an end of the elongated rigid member.

2. The portable power supply of claim 1, wherein the handle is a telescoping handle.

3. The portable power supply of claim 1, wherein the frame defines a longitudinal axis, wherein the elongated rigid member axially moves along the longitudinal axis upon actuation of the actuator.

4. The portable power supply of claim 3, wherein the lock assembly includes a bias configured to urge the pin member along a locking axis and wherein the locking axis is transverse to the longitudinal axis.

5. The portable power supply of claim 1, wherein the elongated rigid member includes another end opposite the end coupled to the actuator.

6. The portable power supply of claim 1, wherein the wedge member includes a slanted wall opposite the end of the elongated rigid member that is coupled to the wedge member, the slanted wall configured to engage the pin member.

7. The portable power supply of claim 6, wherein the pin member includes a slanted wall configured to engage the slanted wall of the wedge member.

8. The portable power supply of claim 1, wherein the lock housing includes
a first lock housing end received in the tube,
a second lock housing end opposite the first housing end, the second lock housing end including a collar, and
an aperture defined in the lock housing between the first and second lock housing ends.

9. The portable power supply of claim 8, wherein the tube includes an aperture defined therein, wherein the frame includes an aperture defined therein, wherein the apertures of the lock housing, the tube, and the frame axially overlap along a longitudinal axis defined by the frame, and wherein the pin member extends into the aperture of the frame in a locked position.

10. The portable power supply of claim 9, wherein the pin member includes a pin and wherein the pin is recessed relative the aperture of the frame in an unlocked position.

11. A portable power supply comprising:
a housing including
an outlet,
a foot, and
an upper surface at least partially defining a plane, the upper surface disposed opposite the foot;
a power source at least partially disposed in the housing, the power source configured to supply power to the outlet; and
a bar pivotably coupled to the housing and configured to pivot about a pivot axis,
wherein the housing includes a recess defined therein, the pivot axis extending through the recess,
wherein in a storage position, the bar is disposed on a side of the plane in common with the foot,
wherein in a standing position, the bar extends away from the foot and intersects the plane.

12. The portable power supply of claim 11, wherein the bar includes an end having a flange and wherein the flange is pivotably coupled to the housing.

13. The portable power supply of claim 12, wherein the end of the bar engages the housing in the recess in the standing position.

14. The portable power supply of claim 11, wherein the bar includes a pair of parallel segments and a pair of angled segments and wherein the pair of angled segments meet in a middle of the bar.

15. The portable power supply of claim 14, wherein the bar includes a horizontal segment that extends between the pair of angled segments.

16. The portable power supply of claim 11, wherein bar defines a diameter being less than 20 millimeters.

17. The portable power supply of claim 11, wherein the housing includes protrusions configured to engage the bar in the storage position.

18. A portable power supply comprising:
a housing;
an outlet disposed on the housing;
a power source at least partially disposed in the housing, the power source configured to supply power to the outlet;
a frame surrounding the housing; and
a handle coupled to the frame, the handle including
a pair of tubes received by the frame, the pair of tubes configured to move relative to the frame,
a grip extending between the pair of tubes,
an actuator received on the grip, the actuator configured to translate along an actuator axis,
an elongated rigid member received within a tube of the pair of tubes, the elongated rigid member configured to move relative to the tube upon actuation of the actuator along the actuator axis, and
a locking assembly including a pin member configured to engage the frame in a locked position,
wherein the pin member is configured to retract in response to actuation of the elongated rigid member.

19. The portable power supply of claim 18, wherein the elongated rigid member moves parallel to the actuator axis.

20. The portable power supply of claim 19, wherein the pin member moves perpendicular to the actuator axis.
